(19) United States
(12) Patent Application Publication
(10) Pub. No.: US 2024/0321330 A1
(43) Pub. Date: Sep. 26, 2024

(54) STORAGE DEVICE INCLUDING BUFFER CHIP AND METHOD FOR PER-PIN TRAINING USING BUFFER CHIP

(71) Applicant: SAMSUNG ELECTRONICS CO., LTD., Suwon-si (KR)

(72) Inventors: Anil KAVALA, Suwon-si (KR); Youngmin Jo, Suwon-si (KR); Jungjune Park, Suwon-si (KR); Chiweon Yoon, Suwon-si (KR)

(73) Assignee: SAMSUNG ELECTRONICS CO., LTD., Suwon-si (KR)

(21) Appl. No.: 18/611,213

(22) Filed: Mar. 20, 2024

(30) Foreign Application Priority Data
Mar. 23, 2023 (KR) 10-2023-0038109

(51) Int. Cl. G11C 7/22; G11C 7/14; H03L 7/099

(52) U.S. Cl. CPC G11C 7/222; G11C 7/14; H03L 7/0998

(57) ABSTRACT

A storage device includes a buffer chip and a memory device. The memory device transmits a random data signal and a data strobe signal to the buffer chip based on a clock signal received from the buffer chip. The buffer chip includes a delay circuit that delays the data strobe signal by a delay time to generate a delayed data strobe signal, a sampler that receives the delayed data strobe signal from the delay circuit and samples the random data signal based on the delayed data strobe signal to generate sampled data, a comparator that compares internal data with the sampled data to generate a comparison result, and a counter module that receives the comparison result from the comparator and determines a target delay based on the comparison result. The buffer chip delays the delayed data strobe signal based on the target delay.

### CROSS-REFERENCE TO RELATED APPLICATION

This application is based on and claims priority under 35 U.S.C. § 119 to Korean Patent Application No. 10-2023-0038109, filed on Mar. 23, 2023, in the Korean Intellectual Property Office, the disclosure of which being incorporated by reference herein in its entirety.

### BACKGROUND

The present disclosure relates to a storage device, and more particularly, to a method of performing per-pin training on a memory device using a buffer chip included in the storage device.

Conventionally, communication within a storage device has been performed at a lower operating frequency compared to a memory system including a high-speed memory such as dynamic random access memory (DRAM) or static random access memory (SRAM). However, in recent years, communication within the storage device has been required to be performed at a high operating frequency. Accordingly, various methods of aligning communication signals have been introduced.

### SUMMARY

It is an aspect to provide a method of performing per-pin training on a memory device using a buffer chip included in the storage device.

According to an aspect of one or more embodiments, there is provided a storage device comprising a buffer chip; and a memory device configured to transmit a random data signal and a data strobe signal to the buffer chip based on a clock signal received from the buffer chip. The buffer chip comprises a delay circuit configured to delay the data strobe signal by a delay time to generate a delayed data strobe signal; a sampler configured to receive the delayed data strobe signal from the delay circuit and sample the random data signal based on the delayed data strobe signal to generate sampled data; a comparator configured to compare internal data with the sampled data to generate a comparison result; and a counter module configured to receive the comparison result from the comparator and determine a target delay based on the comparison result, wherein the buffer chip delays the delayed data strobe signal based on the target delay.

According to another aspect of one or more embodiments, there is provided a buffer chip comprising a clock pin configured to receive a clock signal from outside the buffer chip; a plurality of input/output pins including a first pin configured to provide the clock signal to a plurality of external memory chips and a second pin configured to receive a data signal and a data strobe signal from the plurality of external memory chips; a delay circuit configured to delay the data strobe signal by a delay time to generate a delayed data strobe signal; a sampler configured to sample a random data signal based on the delayed data strobe signal to generate sampled data; a comparator configured to compare internal data with the sampled data to generate a comparison result; and a counter module configured to determine a target delay based on the comparison result.

According to another aspect of one or more embodiments, there is provided a per-pin training method of a storage device including a buffer chip and a memory device, the per-pin training method comprising transmitting, by the memory device, a random data signal and a data strobe signal to the buffer chip based on a clock signal received from the buffer chip; delaying the data strobe signal by a delay time to generate a delayed data strobe signal; sampling the random data signal based on the delayed data strobe signal to generate sampled data; comparing internal data with the sampled data to generates a comparison result; determining a target delay based on the comparison result; and delaying the delayed data strobe signal based on the target delay.

### BRIEF DESCRIPTION OF THE DRAWINGS

Various embodiments will be more clearly understood from the following detailed description taken in conjunction with the accompanying drawings, in which:

FIG. 1 is a schematic block diagram of a storage device according to an embodiment;

FIG. 2 illustrates a memory device of the storage device of FIG. 1, according to an embodiment;

FIG. 3 is a block diagram illustrating a storage device according to an embodiment;

FIG. 4 is a schematic block diagram of a storage device according to an embodiment;

FIG. 5 is a block diagram illustrating a per-pin training operation of a buffer chip using a delay circuit according to an embodiment;

FIGS. 6A and 6B are block diagrams illustrating a per-pin training operation of a buffer chip using a duty control circuit according to various embodiments;

FIGS. 7A, 7B, 7C, and 7D are block diagrams illustrating a per-pin training operation of a buffer chip using a delay circuit, a reference voltage generator, a delay control circuit, and a duty control circuit according to various embodiments;

FIG. 8 is a diagram for explaining a per-pin training operation performed in a storage device according to an embodiment;

FIGS. 9A and 9B are diagrams for explaining a delay training operation performed by a storage device using random data according to various embodiments;

FIG. 10 is a block diagram illustrating a storage device according to an embodiment;

FIGS. 11A and 11B are timing diagrams illustrating a reference voltage training operation in a buffer chip according to various embodiments;

FIG. 12 is a flowchart of per-pin training performed by a storage device according to an embodiment; and

FIG. 13 is a flowchart of an operation of performing per-pin training by using a buffer chip in a storage device according to an embodiment.

### DETAILED DESCRIPTION

A storage device may include a non-volatile memory and a controller for controlling the non-volatile memory. In the related art storage devices, communication between a non-volatile memory and a controller of the storage device has been performed at a lower operating frequency compared to a memory system including a high-speed memory such as dynamic random access memory (DRAM) or static random access memory (SRAM). However, in recent years, communication between the non-volatile memory and the controller has been required to be performed at a high operating frequency. Accordingly, various methods of aligning communication signals between the non-volatile memory and the controller have been introduced.

For example, the storage device may further include a buffer chip between the non-volatile memory device and the controller. The buffer chip may transmit/receive data and commands between the non-volatile memory device and the controller and may perform a control operation on the non-volatile memory device.

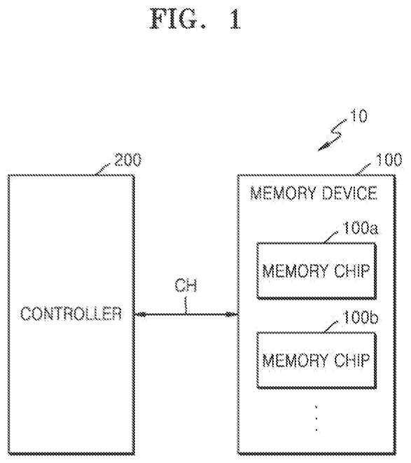

FIG. 1 is a schematic block diagram of a storage device according to an embodiment.

Referring to FIG. 1, a storage device 10 may include a memory device 100 and a controller 200, and the memory device 100 may be a non-volatile memory device including a first memory chip 100a and a second memory chip 100b. The first and second memory chips 100a and 100b may be connected to the controller 200 through a channel CH which is the same for both the first and second memory chips 100a and 100b, and accordingly, the first and second memory chips 100a and 100b may transmit and receive data to and from the controller 200 through the same channel CH.

The memory device 100 may include a plurality of memory chips including at least the first and second memory chips 100a and 100b and may thus be referred to as a ‘multi-chip memory’. For example, each of the first and second memory chips 100a and 100b may be a dual die package (DDP) or a quadruple die package (QDP). However, embodiments are not limited thereto, and in some embodiments, the memory device 100 may be implemented as a multi-die package including a plurality of memory dies including at least a first memory die and a second memory die. Descriptions of the first and second memory chips 100a and 100b below may be equally applied to the first and second memory dies.

When the memory device 100 is implemented as a multi-chip memory, the first and second memory chips 100a and 100b may operate simultaneously. For example, the controller 200 may simultaneously control read operations of the first and second memory chips 100a and 100b. As the data input/output speed between the controller 200 and the memory device 100 increases, the demand for phase alignment between the first and second memory chips 100a and 100b may increase.

According to some embodiments, the second memory chip 100b performs a phase correction operation based on the first memory chip 100a, so that the phases of the first and second signals respectively generated by the first and second memory chips 100a and 100b connected to the same channel CH may be aligned with one another, and thus, the performance and reliability of the memory device 100 may improve. In some embodiments, the memory device 100 may reduce the time required for the phase correction operation by simultaneously performing the duty correction operation and the phase correction operation in a training section, e.g., a duty cycle corrector (DCC) training section.

In some embodiments, each of the first and second memory chips 100a and 100b may be a non-volatile memory chip. For example, each of the first and second memory chips 100a and 100b may be a NAND flash memory chip. For example, at least one of the first and second memory chips 100a and 100b may be a vertical NAND (VNAND) flash memory chip, and a vertical NAND flash memory chip may include word lines vertically stacked on a substrate and cell strings each including a plurality of memory cells respectively connected to the word lines. However, embodiments are not limited thereto, and in some embodiments, at least one of the first and second memory chips 100a and 100b may be a resistive memory chip such as resistive RAM (ReRAM), phase change RAM (PRAM), or magnetic RAM (MRAM).

In some embodiments, the storage device 10 may be an internal memory embedded in an electronic device. For example, the storage device 10 may be a solid state drive (SSD), an embedded universal flash storage (UFS) memory device, and/or an embedded multi-media card (eMMC). In some embodiments, the storage device 10 may be an external memory removable from an electronic device. For example, the storage device 10 may be a UFS memory card, a Compact Flash (CF) memory card, Secure Digital (SD), a Micro Secure Digital (Micro-SD) memory card, a Mini Secure Digital (Mini-SD memory card, an extreme digital (xD) memory card or a memory stick.

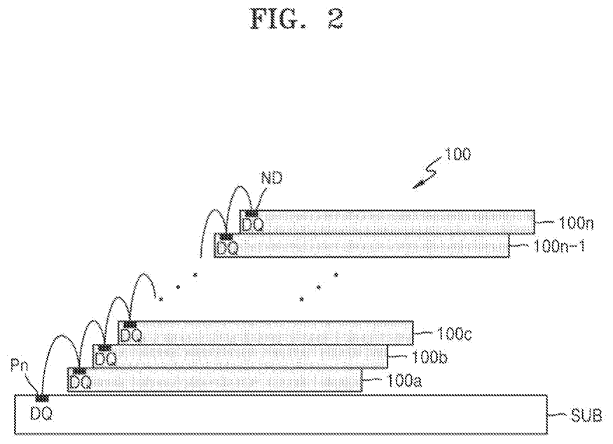

FIG. 2 illustrates the memory device 100 of the storage device 10 of FIG. 1, according to an embodiments.

Referring to FIG. 2, the memory device 100 may include a substrate SUB and a plurality of memory chips 100a to 100n. The plurality of memory chips 100a to 100n may be vertically stacked on the substrate SUB. Input/output pins Pn may be disposed on the substrate SUB, and input/output nodes ND of the plurality of memory chips 100a to 100n may be respectively connected to the input/output pins Pn. For example, the input/output pin Pn and the input/output nodes ND may be connected to each other through wire bonding, and in this configuration, for wire bonding, the plurality of memory chips 100a to 100n may be stacked with a skew in the horizontal direction, as illustrated in FIG. 2.

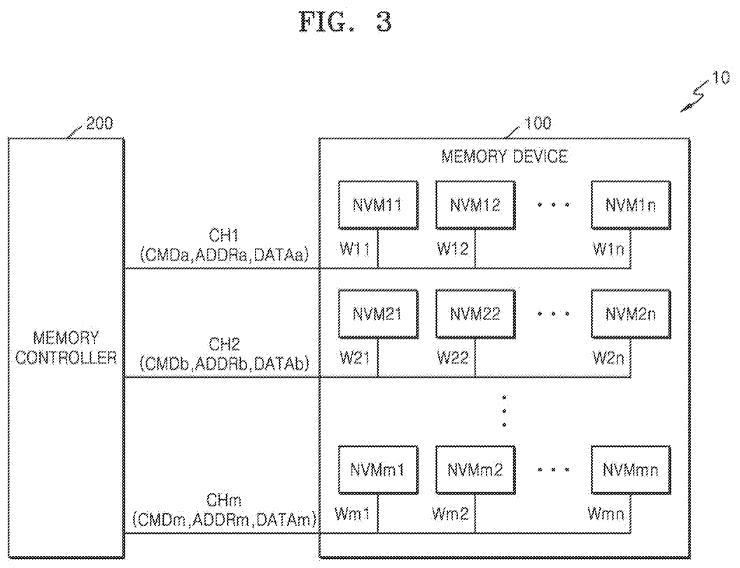

FIG. 3 is a block diagram illustrating a storage device according to an embodiment.

Referring to FIG. 3, the storage device 10 may include a memory device 100 and a memory controller 200. The storage device 10 may support a plurality of channels CH1 to CHm, and the memory device 100 and the memory controller 200 may be connected through the plurality of channels CH1 to CHm. Here, m may be an integer of one or more. For example, in some embodiments, the storage device 10 may be implemented as a storage device such as an SSD.

The memory device 100 may include a plurality of non-volatile memory devices NVM11 to NVMmn. Here, n may be an integer of one or more. Each of the non-volatile memory devices NVM11 to NVMmn may be connected to one of the plurality of channels CH1 to CHm through a corresponding way. For example, the non-volatile memory devices NVM11 to NVM1n may be connected to the first channel CH1 through ways W11 to W1n, and the non-volatile memory devices NVM21 to NVM2n may be connected to the second channel CH2 through ways W21 to W2n. In an embodiment, each of the non-volatile memory devices NVM11 to NVMmn may be implemented as a memory unit capable of operating according to individual commands from the memory controller 200. For example, each of the non-volatile memory devices NVM11 to NVMmn may be implemented as a chip or die, but embodiments are not limited thereto.

The memory controller 200 may transmit and receive signals to and from the memory device 100 through the plurality of channels CH1 to CHm. For example, the memory controller 200 may transmit commands CMDa to CMDm, addresses ADDRa to ADDRm, and data DATAa to DATAm to the memory device 100, or may receive data DATAa to DATAm from the memory device 100, through the channels CH1 to CHm, respectively.

The memory controller 200 may select one of non-volatile memory devices connected to a corresponding channel through each channel and transmit/receive signals to/from the selected non-volatile memory device. For example, the memory controller 200 may select a non-volatile memory device NVM11 from among non-volatile memory devices NVM11 to NVM1n connected to the first channel CH1. The memory controller 200 may transmit the command CMDa, the address ADDRa, and the data DATAa to the selected non-volatile memory device NVM11, or may receive data DATAa from the selected non-volatile memory device NVM11, through the first channel CH1.

The memory controller 200 may transmit and receive signals to and from the memory device 100 in parallel through different channels. For example, while the memory controller 200 transmits the command CMDa to the memory device 100 through the first channel CH1, the command CMDb may be transmitted to the memory device 100 through the second channel CH2. For example, while the memory controller 200 receives data DATAa from the memory device 100 through the first channel CH1, data DATAb may be received from the memory device 100 through the second channel CH2. Here, the term “in parallel” may mean that the memory controller 200 transmits, for example, the commands CMDa and CMDb to the memory device 100 starting at substantially the same time or may mean that there is at least some overlap in the transmission of the commands CMDa and CMDb to the memory device 100. Similarly, the term “in parallel” may mean that the memory controller 200 receives, for example, the data DATAa and DATAb from the memory device 100 starting at substantially the same time or may mean that there is at least some overlap in the reception of the data DATAa and DATAb from the memory device 100.

The memory controller 200 may control overall operations of the memory device 100. The memory controller 200 may control each of the non-volatile memory devices NVM11 to NVMmn connected to the channels CH1 to CHm by transmitting signals to the channels CH1 to CHm. For example, the memory controller 200 may control a selected one of the non-volatile memory devices NVM11 to NVM In by transmitting the command CMDa and the address ADDRa through the first channel CH1.

Each of the non-volatile memory devices NVM11 to NVMmn may operate under the control by the memory controller 200. For example, the non-volatile memory device NVM11 may program data DATAa according to the command CMDa, address ADDRa, and data DATAa provided through the first channel CH1. For example, the non-volatile memory device NVM21 may read data DATAb according to the command CMDb and address ADDRb provided through the second channel CH2, and may transmit the read data DATAb to the memory controller 200.

Although FIG. 3 shows that the memory device 100 communicates with the memory controller 200 through m channels and includes n non-volatile memory devices corresponding to each channel, the number of channels and the number of non-volatile memory devices connected to one channel may be variously changed.

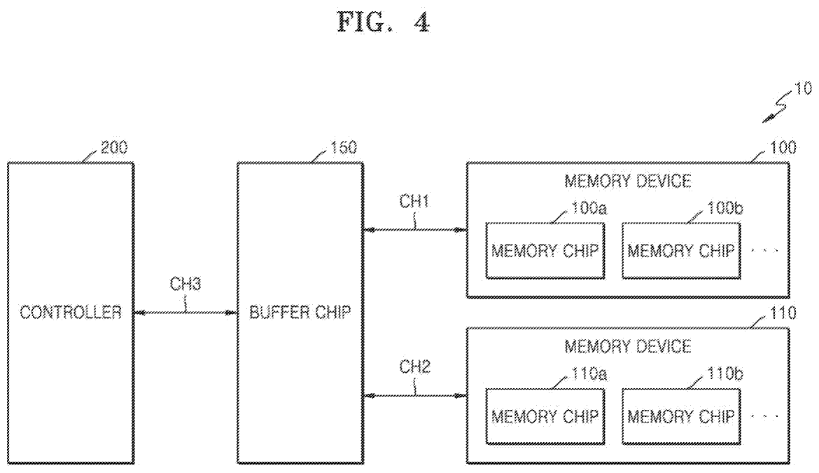

FIG. 4 is a schematic block diagram of a storage device according to an embodiment.

Referring to FIG. 4, the storage device 10 may include a first memory device 100 and a second memory device 110, a buffer chip 150, and a controller 200. The number of memory devices that may be included in the storage device 10 is not limited to the number shown in FIG. 4 and the storage device may include a plurality of memory devices. The first memory device 100 may be connected to the buffer chip 150 through a first channel CH1, the second memory device 110 may be connected to the buffer chip 150 through a second channel CH2, and the buffer chip 150 may be connected to the controller 200 through the third channel CH3. The first memory device 100 includes a plurality of memory chips including at least first and second memory chips 100a and 100b, and accordingly, the plurality of memory chips including the at least first and second memory chips 100a and 100b may transmit and receive data to and from the buffer chip 150 through the first channel CH1. The second memory device 110 includes a plurality of memory chips including at least first and second memory chips 110a and 110b, and accordingly, the plurality of memory chips including the at least first and second memory chips 110a and 110b may transmit and receive data to and from the buffer chip 150 through the second channel CH2. The buffer chip 150 may transmit and receive data to and from the controller 200 through the third channel CH3. For example, the buffer chip 150 may transmit data received from the first memory device 100 and the second memory device 110 through the first channel CH1 and the second channel CH2, or transmit the data to the controller 200 through the third channel CH3, or transmit data received from the controller 200 through the third channel CH3 to the first memory device 100 and the second memory device 110 through the first channel CH1 and the second channel CH2. Hereinafter, an operation in which the storage device 10 performs per-pin training of the first and second memory devices 100 and 110 using the buffer chip 150 will be described in detail.

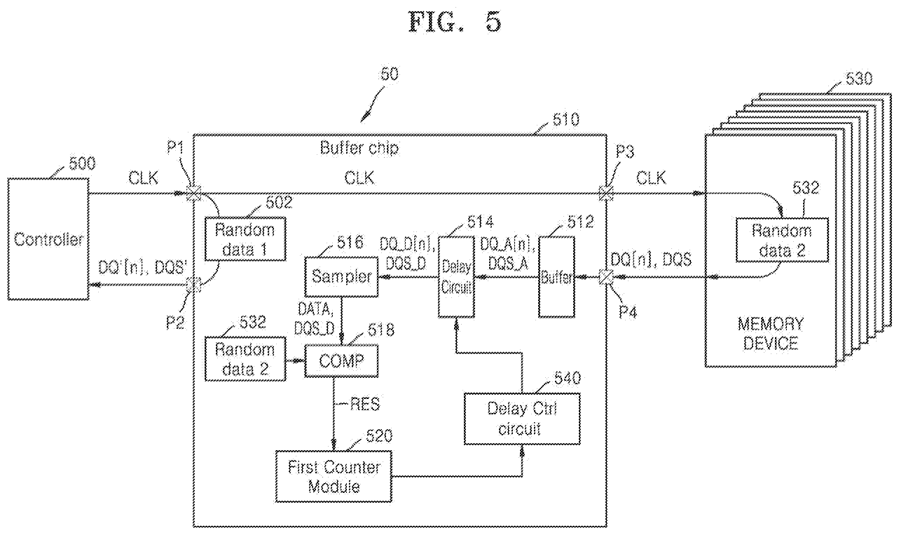

FIG. 5 is a block diagram illustrating a per-pin training operation of a buffer chip using a delay circuit according to an embodiment. FIG. 5 illustrates a storage device 50 including a controller 500, a buffer chip 510 and a plurality of memory devices 530. In some embodiments, the storage device 50, the controller 500, the buffer chip 510 and the plurality of memory devices 530 may correspond respectively to the storage device 10, the controller 200, the buffer chip 150 and the memory devices 110 and 110 illustrated and described with respect to FIG. 4.

The buffer chip 510 may include at least a first pin P1, a second pin P2, a third pin P3, and a fourth pin P4. The buffer chip 510 may receive a clock signal CLK from the controller 500 through the first pin P1 and may transmit a data signal DQ′[n] and a data strobe signal DQS' to the controller 500 through the second pin P2. The buffer chip 510 may transmit the clock signal CLK to the memory device 530 through the third pin P3 and may receive a data signal DQ[n] and a data strobe signal DQS from the memory device 530 through the fourth pin P4. For example, the second pin P2 and the fourth pin P4 may include 8 input/output pins, but embodiments are not limited thereto. The signal lines through which the clock signal CLK, data signals DQ[n] and DQ′[n], and data strobe signals DQS and DQS' are transmitted and received may constitute the channel CH of FIG. 1.

During a read operation on the buffer chip 510, the buffer chip 510 may receive the clock signal CLK, for example, a read enable signal nRE, from the controller 500 and may output the data strobe signal DQS' and the data signal DQ′[n]. During a read operation on the memory device 530, the memory device 530 may receive the clock signal CLK, for example, a read enable signal nRE, from the buffer chip 510, and output the data strobe signal DQS and the data signal DQ[n]. In some embodiments, the clock signal CLK received by the buffer chip 510 from the controller 500 may be the same signal as the clock signal CLK received by the memory device 530 from the buffer chip 510.

The memory device 530 may return a preset signal to the buffer chip 510 in response to receiving the clock signal CLK, and the buffer chip 510 may return a preset signal to the controller 500 in response to receiving the clock signal CLK. When a preset signal is returned, the memory device 530 and the controller 500 may align and transmit phases of a plurality of signals. However, even if the phases of the signals are aligned at the time of transmission, during a communication process, noise may cause a skew in which a difference occurs at a point in time at which a plurality of signals arrive at a transmitter. In order for the device receiving the signal to sample the data signal DQ[n] to generate accurate data DATA, an optimal delay (¼ t_ck) should be applied to the data strobe signal DQS. A delay for the data strobe signal DQS to accurately sample the data signal DQ[n] is referred to as a target delay. If the delay applied to the data strobe signal DQS is not the target delay or if the data skew is not addressed, the possibility that a communication error occurs in the storage device 50 may increase. Accordingly, a method of increasing communication accuracy between the controller 500, the buffer chip 510, and the memory device 530 is required. The storage device 50 may perform training to determine the alignment of the data signal DQ′[n] between the controller 500 and the buffer chip 510 and the target delay of the data strobe signal DQS′, and may perform training to determine the alignment of the data signal DQ[n] between the buffer chip 510 and the memory device 530 and the target delay of the data strobe signal DQS. The storage device 50 may perform training (e.g., read training, and write training, etc.) to increase communication accuracy in performing all functions, and hereinafter, training for aligning the data signal DQ[n] and determining a target delay of the data strobe signal DQS will be described as delay training.

In a Double Data Rate (DDR) mode, the data signal DQ[n] may be sequentially sampled in synchronization with a rising edge and falling edge of the data strobe signal DQS generated based on the clock signal CLK. The data signal DQ[n] may be divided into a logic high section and a logic low section based on a reference voltage level. For example, a section higher than the reference voltage level in the data signal DQ[n] may be a logic high section, and a section lower than the reference voltage level may be a logic low section. Data windows of the data signal may be determined according to a ratio of the logic high section and the logic low section of the data sampled according to the data strobe signal DQS based on the reference voltage level.

If a “duty mismatch” occurs in the data signal DQ[n], the lengths of the logic high section and the logic low section of the data signal DQ[n] may be different from each other, that is, the ratio between the logic high section and the logic low section may not be 1:1. In this case, the data signals may have data windows having different lengths, and effective data windows of the data signals may decrease, and as a result, performance of the storage device 50 may deteriorate. Therefore, it is advantageous to secure an effective data window by performing duty correction based on the reference voltage level to resolve the duty mismatch of the data signal DQ[n]. According to some embodiments, the storage device 50 may perform reference voltage training to determine a reference voltage level for resolving the duty mismatch. According to some embodiments, the storage device 50 may perform duty cycle correction (DCC) training to eliminate a duty mismatch of the data signal DQ[n]. The storage device 50 may adjust the ratio of the logic high section and the logic low section to a desired ratio (e.g., 1:1) using the DCC training. The delay training, reference voltage training, and DCC training may be performed for each of a plurality of pins through which signals are transmitted and received and hereinafter, delay training, reference voltage training, and DCC training are collectively referred to as per-pin training.

When the controller 500 performs per-pin training of the memory device 530 after completing the per-pin training of the buffer chip 510, the time used for per-pin training may be long and inefficient. To shorten the time for per-pin training, at the same time that the controller 500 performs per-pin training on the buffer chip 510, the buffer chip 510 may perform hidden training on the memory device 530. In some embodiments, the clock signal CLK used by the controller 500 to train the buffer chip 510 and the clock signal CLK used by the buffer chip 510 to train the memory device 530 may be the same.

Referring to FIG. 5, the storage device 50 may include the controller 500, the buffer chip 510, and the memory device 530. The buffer chip 510 may include a buffer 512, a delay circuit 514, a sampler 516, a comparator (COMP) 518, a first counter module (COUNTER 1) 520, and a delay control (Ctrl) circuit 540. The first counter module 520 is a counter module for performing delay training, and may include a clock counter that controls internal operations of the first counter module 520, at least one bit counter that tracks bit changes under the control by the clock counter, and an averager. The delay control circuit 540 may transmit a command for the delay circuit 514 to delay the data signal DQ[n] and/or the data strobe signal DQS based on a signal received from the first counter module. The controller 500 and the buffer chip 510 may store first random data (Random Data 1) 502, and each of the memory device 530 and the buffer chip 510 may store second random data (Random Data 2) 532 that is different from the first random data 502. Random data may be data in which a logic high section and a logic low section are randomly switched.

The controller 500 may transmit the clock signal CLK for per-pin training to the buffer chip 510. According to an embodiment, the controller 500 may transmit a clock signal CLK for per-pin training to the buffer chip 510 when the storage device 50 is powered on.

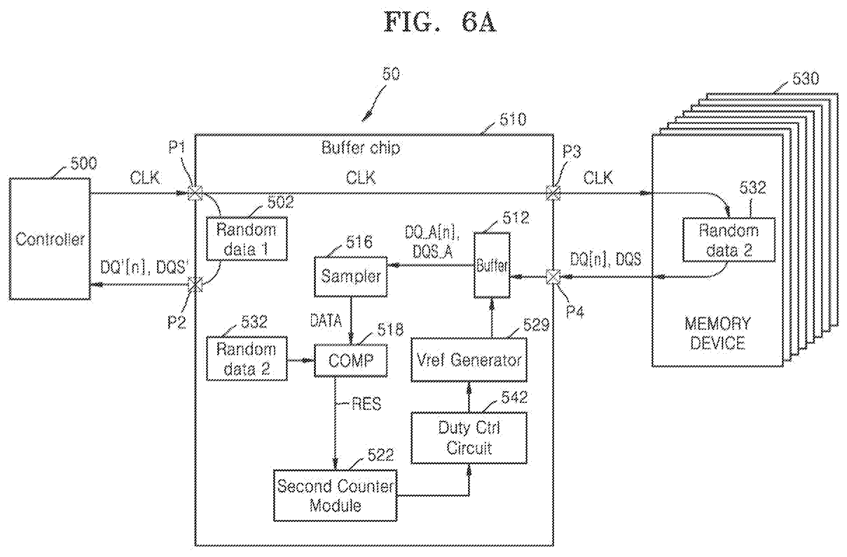

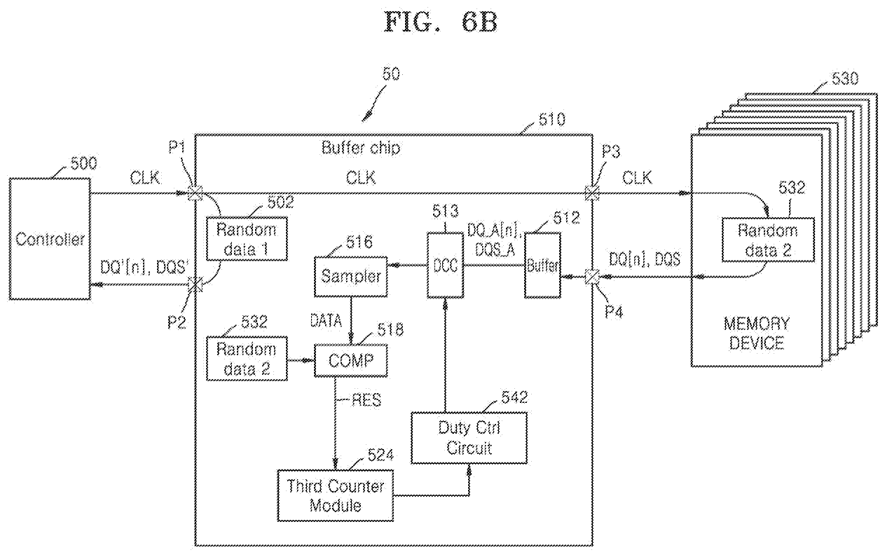

In response to receiving the clock signal CLK from the controller 500 through the first pin P1, the buffer chip 510 may determine a data signal DQ′[n] including at least a portion of the first random data 502. The buffer chip 510 may return the determined data signal DQ′[n] that is determined and the data strobe signal DQS' generated based on the clock signal CLK to the controller 500 through the second pin P2. According to some embodiments, the buffer chip 510 may further include a duty cycle correction circuit (not shown in FIG. 5), and before the returning the determined data signal DQ′[n] and the data strobe signal DQS' to the controller 500, the buffer chip 510 may resolve the duty mismatch of the signal by using the duty cycle correction circuit. An embodiment in which the buffer chip 510 resolves a duty mismatch of a signal by using a duty cycle correction circuit will be described later in detail with reference to FIG. 6B.

For per-pin training of the memory device 530, the buffer chip 510 may transmit the clock signal CLK received from the controller 500 to the memory device 530 through a third pin P3. The memory device 530 may receive the clock signal CLK and determine a data signal DQ[n] including at least a part of the second random data 532. The memory device 530 may transmit the data strobe signal DQS generated based on the determined data signal DQ[n] and the clock signal CLK to the buffer chip 510. According to an embodiment, the memory device 530 may resolve a duty mismatch between the data signal DQ[n] and the data strobe signal DQS before transmitting the data signal DQ[n] and the data strobe signal DQS to the buffer chip 510. However, even if the memory device 530 resolves the duty mismatch during transmission, the duty mismatch may occur again during communication with (e.g., in the process of communicating with) the buffer chip 510.

The buffer chip 510 may receive the data signal DQ[n] and the data strobe signal DQS through the fourth pin P4. The buffer chip 510 may input the data signal DQ[n] and the data strobe signal DQS received through the fourth pin P4 to the buffer 512. For example, in some embodiments, the buffer 512 may include a plurality of buffers respectively buffering the data signal DQ[n] and the data strobe signal DQS. The buffer 512 temporarily stores the data signal DQ[n] and the data strobe signal DQS, and the buffer 512 transmits the amplified data signal DQ_A[n] and amplified data strobe signal DQS_A obtained by amplifying the data signal DQ[n] and the data strobe signal DQS to the delay circuit 514.

The delay circuit 514 delays the amplified data signal DQ_A[n] and the amplified data strobe signal DQS_A, so that the delayed data signal DQ_D[n] and the delayed data strobe signal DQS_D may be transmitted to the sampler 516. For example, in some embodiments, the delay circuit 514 may include a plurality of delay circuits respectively delaying the amplified data signal DQ_A and the amplified data strobe signal DQS_A. The delay circuit 514 may delay the amplified data strobe signal DQS_A by a unit time to find a target delay of the data strobe signal DQS. The delay circuit 514 may adjust a delay time applied to the data strobe signal DQS in response to a signal received from the delay control circuit 540. For example, the delay circuit 514 may increase or decrease a delay time applied to the data strobe signal DQS in response to a signal received from the delay control circuit 540. The delay circuit 514 may adjust a target delay by repeatedly receiving a signal from the delay control circuit 540 and adding or removing a delay time by a unit time.

According to an embodiment, a phase difference may occur between the amplified data signals DQ_A[n] due to communication noise. Accordingly, the delay circuit 514 may align the phases of the data signals DQ[n] by adjusting the delay time for each data signal DQ[n]. For example, when the first data signal among the data signals DQ[n] is delayed by t seconds with respect to the second data signal among the data signals DQ[n], the delay circuit 514 may advance the first data signal by t seconds or apply a delay time by t seconds to the second data signal to align the phases of the first and second data signals.

The sampler 516 may obtain data DATA by sampling the data signal DQ[n] at the rising edge and the falling edge of the delayed data strobe signal DQS_D. Since the data signals DQa to DQn include a plurality of signals received through a plurality of channels, data DATAa to DATAn obtained by sampling the data signals DQa to DQn may also be plural. When a suitable delay time is applied to each data signal DQa to DQn and the data strobe signal DQS in the delay circuit 514, the data DATAa to DATAn obtained by the sampler 516 may be the same data as the second random data 532. The sampler 516 may transmit the obtained data DATAa to DATAn to the comparator 518.

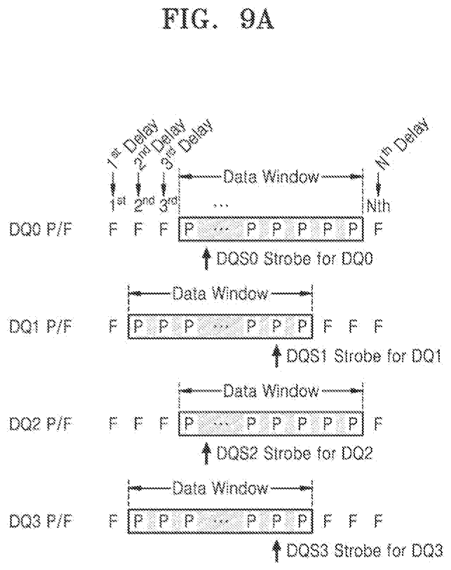

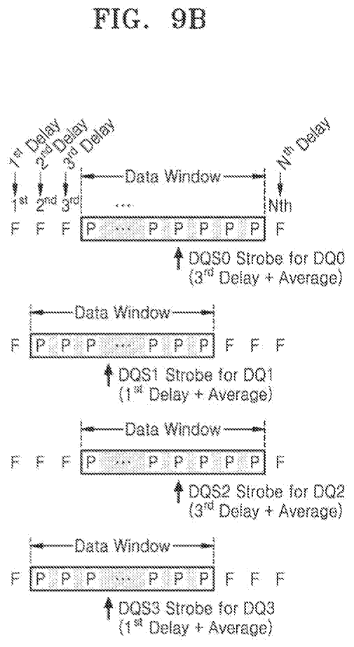

The comparator 518 may compare the data DATAa to DATAn to the second random data 532. The comparator 518 checks whether the data DATAa to DATAn corresponding to the respective data signals DQa to DQn are the same as the second random data 532 to determine a pass/fail. The comparator 518 may determine pass if the data signal DQ is equal to the second random data 532 and fail if the data signal DQ is not equal to the second random data 532. Since the delayed data strobe signal DQS_D and sampled data DATAa to DATAn based on the delayed data strobe signal DQS_D are sequentially input, the comparator 518 may sequentially determine pass/fail. According to an embodiment, when the delay of the data strobe signal DQS sequentially increases, the pass/fail map may have a shape in which a fail section, a pass section, and a fail section appear sequentially. (See, e.g., FIGS. 9A and 9B below). A pass section of the pass/fail map may correspond to a data window section, and a ratio of lengths of successive fail sections and pass sections may mean a duty cycle. The comparator 518 may sequentially transmit, to the first counter module 520, the comparison result RES of the sampled data DATAa to DATAn and second random data 532 based on the delayed data strobe signal DQS_D.

The first counter module 520 may determine a target delay using at least one bit counter and an averager. The first counter module 520 may receive the data strobe signal DQS and internally provide a clock signal CLK used for the operation of the first counter module 520. The first counter module 520 sequentially may obtain a comparison result RES from the comparator 518. For example, the first counter module 520 sequentially may obtain the comparison result RES of the sampled data DATAa to DATAn and second random data 532 from the comparator 518 based on the delayed data strobe signal DQS_D. For example, in some embodiments, the first counter module 520 may include a first counter and a second counter. The first counter may store a first delay at a time point at which the comparison result RES is changed from fail to pass. For example, in some embodiments, the first counter may count a transition (e.g., may trip or toggle at a transition) from fail to pass as the first delay. The second counter may store a second delay when the comparison result RES is changed from pass to fail. For example, in some embodiments, the second counter may count a transition (e.g., may trip or toggle at a transition) from pass to fail as the second delay. (See, e.g., FIG. 9A). The first counter module 520 may calculate the target delay by calculating an average value of the first delay stored in the first counter and the second delay stored in the second counter. Since the section between the first delay and the second delay is the pass window, the average value of the first delay and the second delay may be the center of the pass window. Since the data strobe signal DQS is delayed by the determined target delay, when data is transmitted and received between the buffer chip 510 and the memory device 530, accuracy of the sampled data DATA may be increased and the possibility of communication errors may be reduced.

The delay control (Ctrl) circuit 540 may receive a signal from the first counter module 520 and may transmit a delay time increase signal to the delay circuit 514. According to an embodiment, the signal may include the target delay determined by the first control module 520. Since the target delay is determined by the first counter module 520 based on both the first delay and the second day, until the second delay is determined (i.e., until the comparison result RES changes from pass to fail) the first control module 520 does not output the signal including the target delay and the delay control circuit 540 outputs the delay time increase signal to the delay circuit 514. Once the second delay is determined by the first counter module 520, the first counter module 520 generates the target delay and transmits the signal including the target delay to the delay control circuit 540.

According to an embodiment, when at least one of the first delay and the second delay is not determined by the first counter module 520, the delay control circuit 540 may transmit a delay time increase signal to the delay circuit 514. When the second delay is determined, the first counter module 520 may determine a target delay based on the first delay and the second delay and transmit a signal indicating that the delay time has been determined to the delay control circuit 520. The delay control circuit 520 may not transmit a delay time increase signal to the delay circuit 514 in response to receiving the delay time determining signal.

FIGS. 6A and 6B are block diagrams illustrating a per-pin training operation of a buffer chip using a duty control circuit according to various embodiments. FIG. 6A shows a per-pin training operation of a buffer chip using a reference voltage generator and a duty control circuit, according to an embodiment.

FIG. 6B shows a per-pin training operation of a buffer chip using a duty cycle correction circuit and a duty control circuit, according to an embodiment.

The storage device 50 may determine a logic high section and a logic low section of the data signal based on the reference voltage.

That is, the reference voltage may determine the duty cycle of the data signal DQ[n]. The storage device 50 may determine a section having a higher voltage level than the reference voltage among the data signals DQ[n] as a logic high section and determine a section having a voltage level lower than the reference voltage among the data signals DQ[n] as a logic low section. When the reference voltage is excessively high, the logic high section is shortened, and when the reference voltage is excessively low, the logic low section is shortened, resulting in signal distortion. Therefore, it is advantageous to properly determine the reference voltage level for signal integrity (SI). Hereinafter, a reference voltage level at which a ratio of a logic high section to a logic low section is 1:1 is referred to as a target reference voltage level. Referring to FIG. 6A, the buffer chip 510 may include a second counter module 522, a duty control (Ctrl) circuit 542, and a reference voltage (Vref) generator 529.

The second counter module 522 may perform a counter operation for reference voltage training. For example, the second counter module 522 may accumulate and store the pass/fail status received from the comparator 518, and transmit a target reference voltage level determining signal to the duty control circuit 542 based on the accumulated pass/fail results. The duty control circuit 542 may control the reference voltage level by transmitting a reference voltage rising signal or a reference voltage falling signal to the reference voltage generator 529 based on the target reference voltage level determining signal received from the second counter module 522. The reference voltage generator 529 may adjust the reference voltage level. The reference voltage is input to the sampler 516 via the buffer 512, and the sampler 516 may generate data DATA by sampling the data signal DQ[n] based on the reference voltage and the data strobe signal DQS. The comparator 518 may compare the data DATA generated based on the reference voltage level with the second random data 532 to determine the pass/fail.

The comparator 518 may determine a comparison result as pass when the data DATA generated based on the reference voltage level and the second random data 532 match and determine a comparison result as fail when the data DATA generated based on the reference voltage level and the second random data 532 do not match. The comparison result REF may be transferred to the reference voltage generator 529 through the second counter module 522 and the duty control circuit 542. The reference voltage generator 529 may sequentially increase (or decrease) the reference voltage.

For example, the reference voltage generator 529 may set an initial reference voltage close to a logic low level and sequentially increase subsequent reference voltages by a unit voltage. According to some embodiments, the reference voltage generator 529 may adjust the reference voltage based on the obtained comparison result. For example, the reference voltage generator 529 may check the duty cycle of the sampled data and adjust the reference voltage level so that the ratio of the logic high section to the logic low section is 1:1. The sampler 516 may sequentially sample the data signal DQ[n] based on the sequentially changed reference voltage, and the comparator 518 may sequentially compare the sampled data DATA with the second random data 532 to determine pass/fail to generate a pass/fail map. The second counter module 522 may determine a target reference voltage level by obtaining a comparison result.

A plurality of bit counters included in the second counter module 522 may store a first reference voltage level at the time point at which the comparison result is changed from fail to pass, and a second reference voltage level at a time point at which the comparison result is changed from pass to fail. The averager may calculate an average value based on the first reference voltage level and the second reference voltage level. An average value of the first reference voltage level and the second reference voltage level may be a target reference voltage level such that a ratio of a logic high section and a logic low section of the data signal DQ[n] is 1:1.

Referring to FIG. 6B, the buffer chip 510 may include a third counter module 524, a duty control (Ctrl) circuit 542, and a duty cycle corrector circuit (DCC) 513, according to an embodiment.

The third counter module 524 may perform a counter operation for DCC training. For example, the third counter module 524 may accumulate and store pass/fail information received from the comparator 518 and transmit the accumulated pass/fail result to the duty control circuit 542. The duty control circuit 542 may transmit a DCC control signal to the DCC 513 based on the pass/fail result received from the second counter module 522, so that a ratio of a logic high section and a logic low section of the sampled data signal may be controlled. The DCC 513 may perform an operation of correcting the duty of the data signal using various methods.

For example, in some embodiments, the DCC 513 may correct the duty of the data signal using a phase interpolation method. The DCC 513 may adjust the length ratio of the logic high section and logic low section of the data signal in stages, so that the ratio of the logic high section and the logic low section of the data signal may be controlled to be a desired ratio.

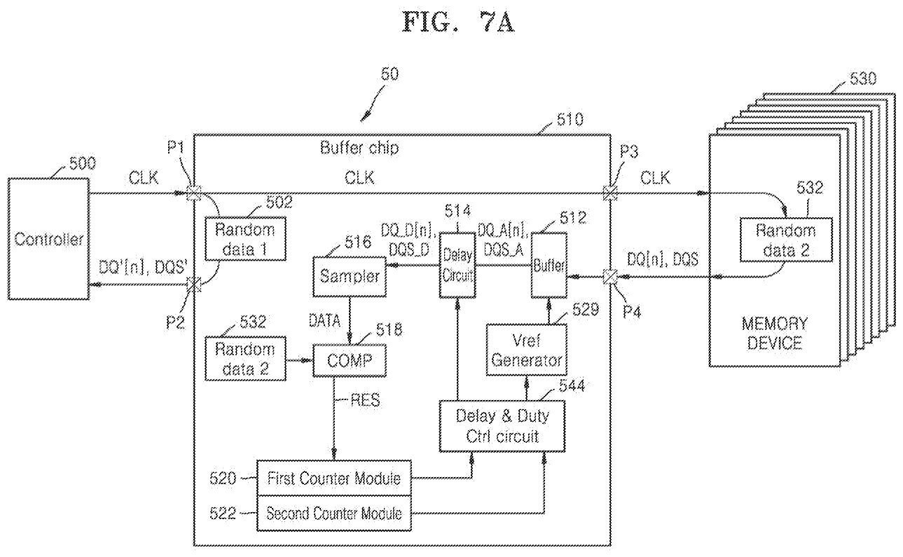

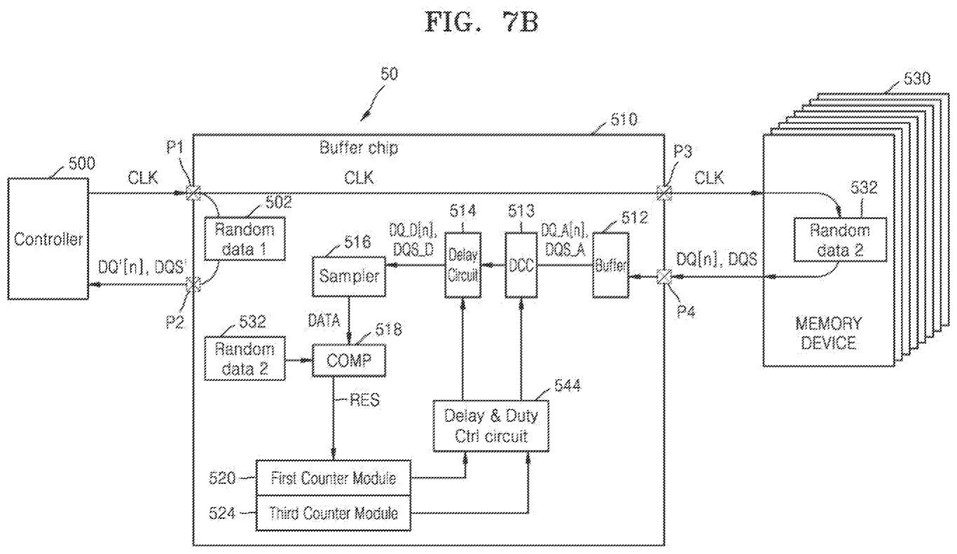

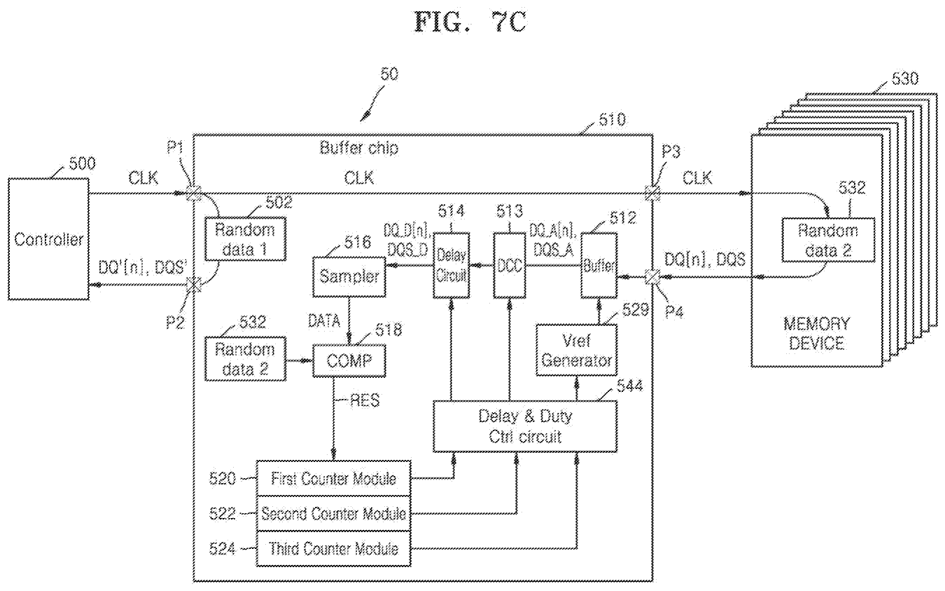

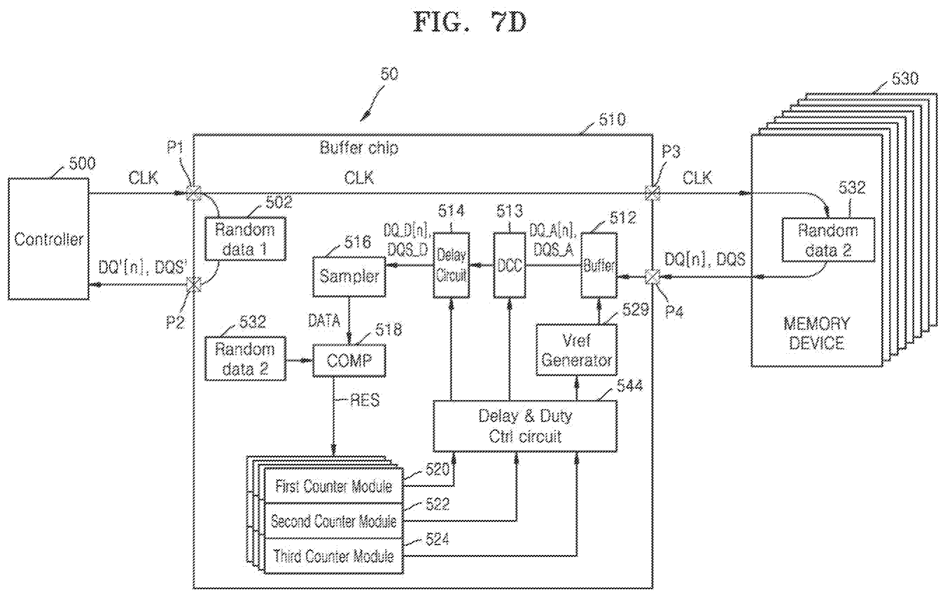

FIGS. 7A, 7B, 7C, and 7D are block diagrams illustrating a per-pin training operation of a buffer chip using a delay circuit, a reference voltage generator, a delay control circuit, and a duty control circuit according to various embodiments.

Descriptions of the same contents as those described in FIGS. 5, 6A, and 6B will be omitted for conciseness. Referring to FIG. 7A, in some embodiments, the buffer chip 510 may include both a delay circuit 514 and a reference voltage (Vref) generator 529.

The buffer chip 510 may include a delay & duty control (Ctrl) circuit 544 for performing delay training using the delay circuit 514 and reference voltage training using the reference voltage generator 529. The delay circuit 514 may adjust delay times of the data signal DQ[n] and the data strobe signal DQS to eliminate skew and adjust a time point for sampling the data signal DQ[n]. The reference voltage generator 529 may perform duty cycle correction of the data signal DQ[n] by adjusting the reference voltage level. According to some embodiments, if the comparator 518 in FIGS. 5, 6A, and 6B determines a comparison result for one factor (e.g., delay time-pass or fail or a reference voltage level-pass or fail), the comparator 518 in FIG. 7A may determine a comparison result for two factors (delay time & reference voltage level-pass or fail).

For example, the comparator 518 may generate a look-up table mapping pass/fail results for arbitrary combinations of delay times and reference voltage levels. The buffer chip 510 may include a first counter module 520 for delay training and a second counter module 522 for reference voltage training.

The first counter module 520 may be used to determine the alignment of the data signal DQ[n] and/or the target delay of the data strobe signal, and the second counter module 522 may be used to determine the target reference voltage level. For example, as described above, the first counter module 520 may store the first delay time at a time point at which the pass/fail result according to the delay time is changed from fail to pass, and the second delay time of the time point at which the pass/fail result according to the delay time changes from pass to fail. The first counter module 520 may determine a target delay based on the first delay time and the second delay time. For example, as described above, the second counter module 522 may store the first reference voltage level at a time point at which the pass/fail result according to the reference voltage level is changed from fail to pass, and the second reference voltage level at the time point at which the pass/fail result according to the reference voltage level changes from pass to fail. The second counter module 522 may determine the target reference voltage level by calculating an average value of the first reference voltage level and the second reference voltage level.

Referring to FIG. 7B, the buffer chip 510 may include both a delay circuit 514 and a DCC 513.

In some embodiments, the buffer chip 510 may include a delay & duty control (Ctrl) circuit 544 for performing delay training using the delay circuit 514 and DCC training using the DCC 513. The buffer chip 510 may improve signal integrity more efficiently by using the delay circuit 514 and the DCC 513 similarly to that described with reference to FIG. 7A.

Referring to FIG. 7C, the buffer chip 510 may include a delay circuit 514, a DCC 513, and a reference voltage (Vref) generator 529.

In some embodiments, the buffer chip 510 may include a delay & duty control circuit 544 for performing delay training using the delay circuit 514, DCC training using the DCC 513, and reference voltage training using the reference voltage generator 529. The buffer chip 510 may improve signal integrity more efficiently by using the delay circuit 514, the DCC 513, and the reference voltage generator 529, similarly to FIG. 7A.

Referring to FIG. 7D, in some embodiments, the buffer chip 510 may include a plurality of counter modules corresponding to multi-die packaging.

Multi-die packaging is technology for producing semiconductors by integrating a plurality of dies in one package. In some embodiments, the buffer chip 510 may include a plurality of the first counter modules 520, a plurality of the second counter modules 522, and a plurality of the third counter modules 524, so that the training method using the delay circuit 514, the DCC 513, and the reference voltage generator 529 described with reference to FIGS. 5 to 7C may be applied to each memory die.

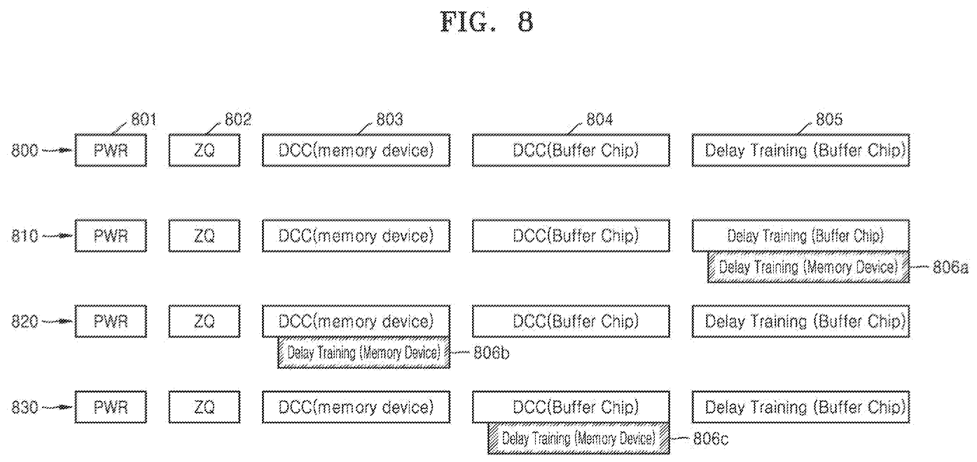

FIG. 8 is a diagram for explaining a per-pin training operation performed in a storage device according to an embodiment.

The process 800 according to a comparative example according to the related art may, after power-on 801 of the storage device, sequentially perform ZQ calibration 802, DCC training 803 in the memory device, and DCC training 804 and delay training 805 (e.g., read training and/or write training) in the buffer chip.

In process 800, delay training for the memory device may be performed only after the delay training 805 for the buffer chip is completed. By contrast, in the per-pin training method according to various embodiments, delay training between a buffer chip and a memory device may be performed at various time points.

Referring to FIG. 8, in the per-pin training method according to various embodiments, delay training between a buffer chip and a memory device may be performed at various time points. For example, in process 810 of an embodiment, delay training 806b of the memory device (e.g., hidden read training) may be performed while delay training is performed on the buffer chip. In process 820 of an embodiment, delay training 806b between the buffer chip and the memory device may be performed while DCC training 803 is performed on the memory device. In process 830 of an embodiment, delay training 806c between the buffer chip and the memory device may be performed while DCC training 804 is performed on the buffer chip. In the process 800 according to the related art, since the controller manages all training, two delay trainings cannot be performed at the same time. By contrast, in the per-pin training method according to various embodiments, since delay training for a memory device may be performed in a buffer chip, two delay trainings may be performed simultaneously. Accordingly, the time required for training the storage device including the buffer chip is reduced.

FIGS. 9A and 9B are diagrams for explaining a delay training operation performed by a storage device using random data according to an embodiment.

FIG. 9A shows a pass/fail map of the data signal DQ[n] and an edge (rising edge or falling edge) of the data strobe signal DQS before per-pin training is performed.

As described with reference to FIGS. 5 to 7D, the counter module may generate a pass/fail map of the data signal DQ[n] based on the obtained comparison result RES.

The first data signal DQ0 has a data window (pass window) of 4^{th} delay to N-1^{th} delay, the data window of the second data signal DQ1 is 2^{th} delay to N-3^{th} delay, the data window of the third data signal DQ2 may be 4^{th} delay to N-1^{th} delay, and the data window of the fourth data signal DQ3 may be 2^{th} delay to N-3^{th} delay. Although only four data signals are shown in FIGS. 9A and 9B, embodiments are not limited thereto. Before performing per-pin training, the edge of the data strobe signal may be located out of the center of the data window. For example, referring to FIG. 9A, positions of the first data strobe signal DQS0 and the third data strobe signal DQS2 may be a position deviated from the center of the data window of the first data signal DQ0 and the third data signal DQ2 to the left. Positions of the second data strobe signal DQS1 and the fourth data strobe signal DQS3 may be a location deviated from the center of the data window of the second data signal DQ1 and the fourth data signal DQ3 to the right. Accordingly, an error may occur when sampling the data signal DQ.

FIG. 9B shows a pass/fail map of the data signal DQ[n] and an edge of the data strobe signal DQS after per-pin training is performed.

Referring to FIG. 9B, after per-pin training is performed, the position of the data strobe signal may be located at the center of the data window of each data signal.

The counter module (e.g., the counter module 520 of FIG. 5) may determine target delays of the data strobe signals DQS0 to DQS3 of the respective data signals DQ0 to DQ3 using the average of the delay times obtained from the first counter and the second counter. Thus, the buffer chip 510 may apply a target delay to the existing data strobe signal. The counter module may apply a target delay to the existing data strobe signal, so that the edge position of the data strobe signal may be adjusted to minimize the possibility of error in data sampling. For example, referring to FIG. 9B, the edge of the first data strobe signal DQS0 may be changed to be located in the center of the data window of the first data signal DQ0, the edge of the second data strobe signal DQS1 may be changed to be located at the center of the data window of the second data signal DQ1, the edge of the third data strobe signal DQS2 may be changed to be located at the center of a data window of the third data signal DQ2, and the edge of the fourth data strobe signal DQS3 may be located at the center of a data window of the fourth data signal DQ3.

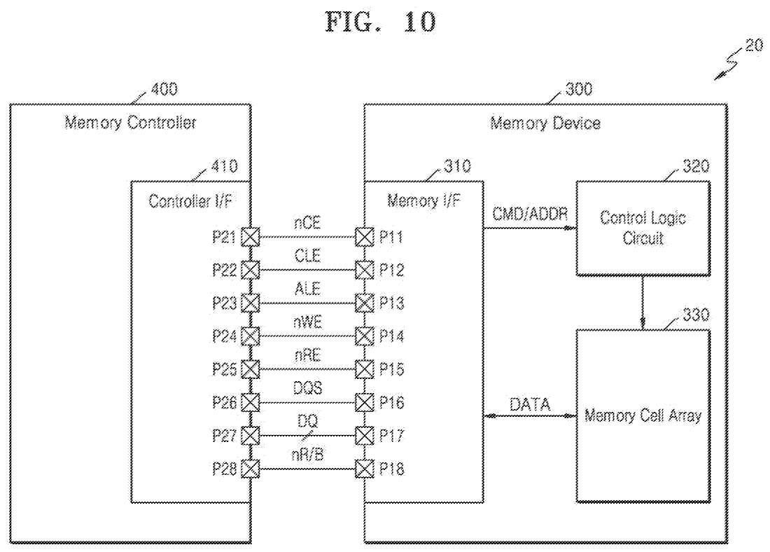

FIG. 10 is a block diagram illustrating a storage device according to an embodiment.

Referring to FIG. 10, a storage device 20 may include a memory device 300 and a memory controller 400.

The memory device 300 may correspond to one of the non-volatile memory devices NVM11 to NVMmn communicating with the memory controller 200 based on one of the plurality of channels CH1 to CHm of FIG. 3. The memory controller 400 may correspond to the memory controller 200 of FIG. 3. The memory device 300 may include first to eighth pins P11 to P18, a memory interface I/F 310, a control logic circuit 320, and a memory cell array 330.

The memory I/F 310 may receive the chip enable signal nCE from the memory controller 400 through the first pin P11.

The memory I/F 310 may transmit/receive signals to/from the memory controller 400 through the second to eighth pins P12 to P18 according to the chip enable signal nCE. For example, when the chip enable signal nCE is in an enable state (e.g., low level), the memory I/F 310 may transmit/receive signals to/from the memory controller 400 through the second to eighth pins P12 to P18. The memory I/F 310 may receive a command latch enable signal CLE, an address latch enable signal ALE, and a write enable signal nWE from the memory controller 400 through the second to fourth pins P12 to P14.

The memory I/F 310 may receive the data signal DQ from the memory controller 400 through the seventh pin P17 or transmit the data signal DQ to the memory controller 400. A command CMD, an address ADDR, and data may be transmitted through the data signal DQ. For example, the data signal DQ may be transmitted through a plurality of data signal lines. In this case, the seventh pin P17 may include a plurality of pins corresponding to a plurality of data signals. The memory I/F 310 may obtain the command CMD from the data signal DQ received in the enable section (e.g., high level state) of the command latch enable signal CLE based on the toggle timings of the write enable signal nWE.

The memory I/F 310 may obtain the address ADDR from the data signal DQ received in the enable section (e.g., high level state) of the address latch enable signal ALE based on the toggle timings of the write enable signal nWE. In an embodiment, the write enable signal nWE may be toggled between a high level and a low level while maintaining a static state (e.g., a high level or a low level).

For example, the write enable signal nWE may be toggled in a section in which the command CMD or the address ADDR is transmitted. Accordingly, the memory I/F 310 may obtain the command CMD or the address ADDR based on the toggle timings of the write enable signal nWE. The memory I/F 310 may receive the read enable signal nRE from the memory controller 400 through the fifth pin P15.

The memory I/F 310 may receive the data strobe signal DQS from the memory controller 400 or transmit the data strobe signal DQS to the memory controller 400 through the sixth pin P16. In the data output operation of the memory device 300, the memory I/F 310 may receive the read enable signal nRE toggling through the fifth pin P15 before outputting the data DATA.

The memory I/F 310 may generate a toggling data strobe signal DQS based on the toggling of the read enable signal nRE. For example, the memory I/F 310 may generate a data strobe signal DQS that starts toggling after a preset delay (e.g., tDQSRE) based on the toggling start time of the read enable signal nRE. The memory I/F 310 may transmit the data signal DQ including the data DATA based on the toggle timing of the data strobe signal DQS. Accordingly, the data DATA may be aligned with the toggle timing of the data strobe signal DQS and transmitted to the memory controller 400. In the data input operation of the memory device 300, when the data signal DQ including the data DATA is received from the memory controller 400, the memory I/F 310 may receive the data strobe signal DQS toggling together with the data DATA from the memory controller 400.

The memory interface I/F 310 may obtain data DATA from the data signal DQ based on the toggle timing of the data strobe signal DQS. For example, the memory I/F 310 may obtain the data DATA by sampling the data signal DQ at rising edges and falling edges of the data strobe signal DQS. The memory I/F 310 may transmit the ready/busy output signal nR/B to the memory controller 400 through the eighth pin P18.

The memory I/F 310 may transmit state information of the memory device 300 to the memory controller 400 through the ready/busy output signal nR/B. When the memory device 300 is in a busy state (i.e., when internal operations of the memory device 300 are being performed), the memory I/F 310 may transmit a ready/busy output signal nR/B indicating a busy state to the memory controller 400. When the memory device 300 is in a ready state (i.e., when internal operations of the memory device 300 are not performed or completed), the memory I/F 310 may transmit a ready/busy output signal nR/B indicating a ready state to the memory controller 400. For example, while the memory device 300 reads data DATA from the memory cell array 330 in response to a page read command, the memory I/F 300 may transmit a ready/busy output signal nR/B indicating a busy state (e.g., a low level) to the memory controller 400. For example, while the memory device 300 programs data DATA into the memory cell array 330 in response to a program command, the memory I/F 310 may transmit a ready/busy output signal nR/B indicating a busy state to the memory controller 400. The control logic circuit 320 may generally control various operations of the memory device 300.

The control logic circuit 320 may receive a command/address CMD/ADDR from the memory I/F 310. The control logic circuit 320 may generate control signals for controlling other components of the memory device 300 according to the received command/address CMD/ADDR. For example, the control logic circuit 320 may generate various control signals for programming data DATA in the memory cell array 330 or reading data DATA from the memory cell array 330. The memory cell array 330 may store data DATA obtained from the memory I/F 310 under the control by the control logic circuit 320.

The memory cell array 330 may output the stored data DATA to the memory I/F 310 under the control by the control logic circuit 320. The memory cell array 330 may include a plurality of memory cells.

For example, the plurality of memory cells may be flash memory cells. However, embodiments are not limited thereto, and the memory cells may be a resistive random access memory (RRAM) cell, a ferroelectric random access memory (FRAM) cell, a phase change random access memory (PRAM) cell, a thyristor random access memory (TRAM) cell, or a magnetic random access memory (MRAM) cell. Hereinafter, embodiments will be described focusing on an embodiment in which the memory cells are NAND flash memory cells. The memory controller 400 may include first to eighth pins P21 to P28 and a controller I/F 410.

The first to eighth pins P21 to P28 may correspond to the first to eighth pins P11 to P18 of the memory device 300. The controller I/F 410 may transmit the chip enable signal nCE to the memory device 300 through the first pin P21.

The controller I/F 410 may transmit/receive signals with the memory device 300 selected through the chip enable signal nCE through second to eighth pins P22 to P28. The controller I/F 410 may transmit a command latch enable signal CLE, an address latch enable signal ALE, and a write enable signal nWE to the memory device 300 through the second to fourth pins P22 to P24.

The controller I/F 410 may transmit the data signal DQ to the memory device 300 or receive the data signal DQ from the memory device 300 through the seventh pin P27. The controller I/F 410 may transmit a data signal DQ including a command CMD or an address ADDR together with a toggle write enable signal nWE to the memory device 300.

As the command latch enable signal CLE having an enable state is transmitted, the controller I/F 410 transmits a data signal DQ including a command CMD to the memory device 300, and as the address latch enable signal ALE having an enable state is transmitted, the controller I/F 410 may transmit the data signal DQ including the address ADDR to the memory device 300. The controller I/F 410 may transmit the read enable signal nRE to the memory device 300 through the fifth pin P25.

The controller I/F 410 may receive the data strobe signal DQS from the memory device 300 or may transmit the data strobe signal DQS to the memory device 300 through the sixth pin P26. In the data output operation of the memory device 300, the controller I/F 410 may generate a toggle read enable signal nRE and transmit the read enable signal nRE to the memory device 300.

For example, the controller I/F 410 may generate a read enable signal nRE that is changed from a fixed state (e.g., high level or low level) to a toggle state before data DATA is output. Accordingly, the data strobe signal DQS toggling based on the read enable signal nRE in the memory device 300 may be generated. The controller I/F 410 may receive the data signal DQ including the data DATA together with the toggling data strobe signal DQS from the memory device 300. The controller I/F 410 may acquire data DATA from the data signal DQ based on the toggle timing of the data strobe signal DQS. In a data input operation of the memory device 300, the controller I/F 410 may generate a toggle data strobe signal DQS.

For example, the controller I/F 410 may generate a data strobe signal DQS that changes from a fixed state (e.g., high level or low level) to a toggle state before transmitting data DATA. The controller I/F 410 may transmit the data signal DQ including the data DATA to the memory device 300 based on the toggle timings of the data strobe signal DQS. The controller I/F 410 may receive the ready/busy output signal nR/B from the memory device 300 through the eighth pin P28.

The controller I/F 410 may determine state information of the memory device 300 based on the ready/busy output signal nR/B.

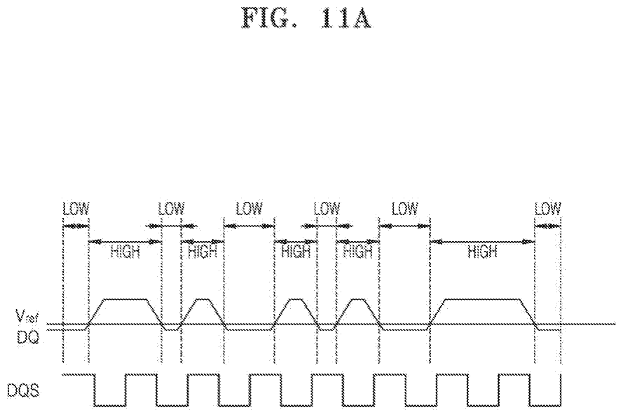

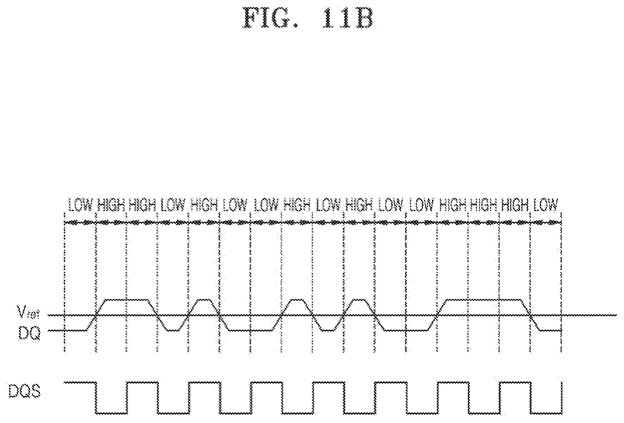

FIGS. 11A and 11B are timing diagrams illustrating a reference voltage training operation in a buffer chip according to an embodiment.

FIG. 11A shows a data signal DQ, a data strobe signal DQS and a reference voltage level Vref.

The sampler may determine a section higher than the reference voltage level of the data signal DQ as a logic high section HIGH and a section lower than the reference voltage level as a logic low section LOW. In FIG. 11A, since the reference voltage level is lower than a target reference voltage level, the logic low section LOW may appear shorter than the logic high section HIGH. Logic-low data may be mistaken for logic-high data if data is sampled when the reference voltage level is lower than the target reference voltage level. Conversely, although not shown, when the reference voltage level is higher than the target reference voltage level, the logic low section LOW may appear longer than the logic high section HIGH. Logic-high data may be mistaken for logic-low data if data is sampled when the reference voltage level is higher than the target reference voltage level. When the reference voltage level is higher or lower than the target reference voltage level, the duty cycle is not 1:1, so there is a high probability of error in data sampling. Therefore, to prevent data from being misjudged, the reference voltage level needs to be changed to a target level.

FIG. 11B shows a case where the reference voltage level is the target reference voltage level.

When the reference voltage level is the target level, the duty cycle may appear as 1:1. Referring to FIG. 11B, it may be seen that the lengths of the logic high section HIGH and the logic low section LOW are similar. The reference voltage generator (e.g., the reference voltage generator 529 of FIG. 6) of various embodiments may perform duty cycle correction by changing the reference voltage level to a target level. A storage device according to various embodiments may include a buffer chip, and a memory device transmitting a random data signal and a data strobe signal to the buffer chip in response to receiving a clock signal from the buffer chip, and the buffer chip may include a delay circuit generating a delayed data strobe signal by delaying the data strobe signal by a delay time, a sampler receiving the delayed data strobe signal from the delay circuit and generating sampled data by sampling the random data signal based on the delayed data strobe signal, a comparator generating a comparison result by comparing internal data with the sampled data, and a counter module receiving the comparison result from the comparator, determining a target delay based on the received comparison result, and delaying the data strobe signal by the target delay.

According to various embodiments, the comparator may determine the comparison result as pass when the internal data and the sampled data are the same and determines the comparison result as fail when the internal data and the sampled data are not identical, and the counter module may include a counter that sequentially receives a plurality of comparison results from the comparator and accumulates and stores the sequentially received plurality of comparison results.

According to various embodiments, the counter module may include a first counter for storing a first delay for adding to the data strobe signal at a time point at which the plurality of comparison results sequentially received change from fail to pass, and for storing a second delay for adding to the data strobe signal at a time point at which the plurality of comparison results sequentially received change from pass to fail, and the counter module may determine an average value of the first delay and the second delay as the target delay.

According to various embodiments, in response to confirming that the second delay is not stored in the first counter, the counter module may provide a delay time increase signal to the delay circuit, and in response to confirming that the second delay is stored in the first counter, the counter module may not provide the delay time increase signal to the delay circuit.

According to various embodiments, the delay circuit may add the delay time to the delayed data strobe signal by a preset time in response to the delay time increase signal obtained from the counter module.

According to various embodiments, the buffer chip may further comprise a reference voltage generator generating a changed reference voltage by changing a reference voltage serving as a sampling standard for the random data signal and a DCC adjusting the duty of the random data signal based on a control signal, and the sampler may generate the sampled data by sampling the random data signal based on the changed reference voltage or sampling a random data signal having an adjusted duty, the comparator may compare the internal data and the sampled data to determine whether the internal data and the sampled data are identical and transmits a determination result to the counter module, and the counter module may include a second counter that stores a first reference voltage level at a time point at which a comparison result changes from fail to pass and stores a second reference voltage level at a time point at which a comparison result changes from pass to fail, and the counter module may determine an average value of the first reference voltage level and the second reference voltage level as a target reference voltage level.

According to various embodiments, in response to confirming that the second reference voltage level is not stored in the second counter, the counter module may provide a reference voltage increase signal to the reference voltage generator and may not provide the reference voltage increase signal to the reference voltage generator in response to confirming that the second reference voltage level is stored in the second counter.

According to various embodiments, the DCC may adjust the duty cycle of the random data signal using a phase interpolation method.

According to various embodiments, the reference voltage generator may increase the reference voltage by a preset value in response to the reference voltage increase signal obtained from the counter module.

According to various embodiments, the internal data may be the same as the random data stored in the memory device, and the internal data may be random data in which a logic high section and a logic low section are randomly switched.

According to various embodiments, the memory device may further include a controller providing a clock signal to the buffer chip, and the buffer chip may provide the clock signal obtained from the controller to the memory device.

According to various embodiments, the buffer chip may further include an input buffer buffering the random data signal.

A buffer chip according to various embodiments may include a plurality of input/output pins including a clock pin configured to receive a clock signal from the outside, a first pin configured to provide the clock signal to external memory chips, and a second pin configured to receive a data signal and a data strobe signal from the external memory chips, a delay circuit generating a delayed data strobe signal by delaying the data strobe signal by a delay time, a sampler generating sampled data by sampling the random data signal based on the delayed data strobe signal, a comparator generating a comparison result by comparing internal data with the sampled data, and a counter module determining a target delay based on the received comparison result.

According to various embodiments, the comparator may determine the comparison result as pass when the internal data and the sampled data are the same and determines the comparison result as fail when the internal data and the sampled data are not identical, and the counter module may include a counter that sequentially receives a plurality of comparison results from the comparator and accumulates and stores the sequentially received plurality of comparison results.

According to various embodiments, the counter module may include a first counter storing a first delay for adding to the data strobe signal at a time point at which the plurality of comparison results sequentially received change from fail to pass, and storing a second delay for adding to the data strobe signal at a time point at which the plurality of comparison results sequentially received change from pass to fail, and the counter module may determine an average value of the first delay and the second delay as the target delay.

According to various embodiments, in response to confirming that the second delay is not stored in the first counter, the counter module may provide a delay time increase signal to the delay circuit, and in response to confirming that the second delay is stored in the first counter, the counter module may not provide the delay time increase signal to the delay circuit.

According to various embodiments, the buffer chip may further comprise a reference voltage generator generating a changed reference voltage by changing a reference voltage serving as a sampling standard for the random data signal and a DCC adjusting the duty of the random data signal based on a control signal, and the sampler generates the sampled data by sampling the random data signal based on the changed reference voltage or sampling a random data signal having an adjusted duty, the comparator compares the internal data and the sampled data to determine whether the internal data and the sampled data are identical and transmits a determination result to the counter module, and the counter module includes a second counter that stores a first reference voltage level at a time point at which a comparison result changes from fail to pass and stores a second reference voltage level at a time point at which a comparison result changes from pass to fail, and the counter module may determine an average value of the first reference voltage level and the second reference voltage level as a target reference voltage level.

According to various embodiments, in response to confirming that the second reference voltage level is not stored in the second counter, the counter module may provide a reference voltage increase signal to the reference voltage generator and may not provide the reference voltage increase signal to the reference voltage generator in response to confirming that the second reference voltage level is stored in the second counter.

According to various embodiments, the reference voltage generator may increase the reference voltage by a preset value in response to the reference voltage increase signal obtained from the counter module.

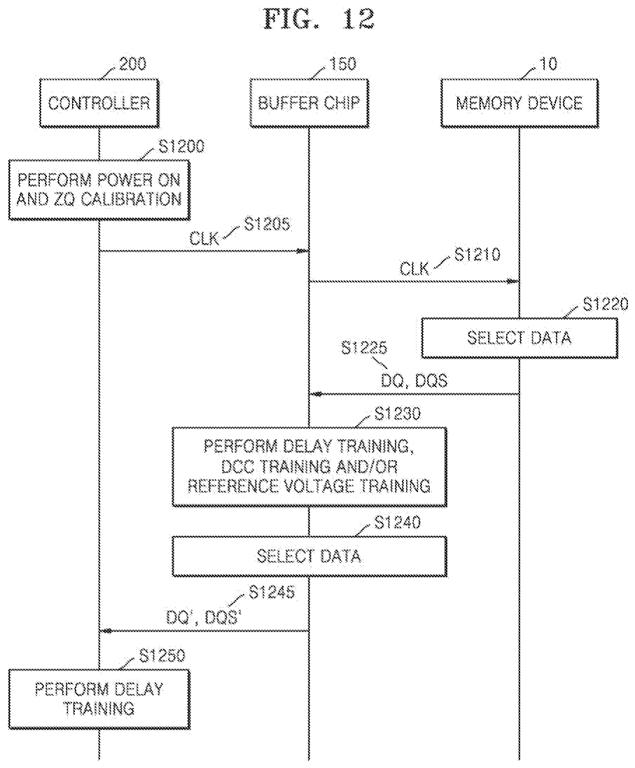

FIG. 12 is a flowchart of per-pin training performed by a storage device, according to an embodiment. For example, the per-pin training may be performed between a controller 200, a buffer chip 150 and a memory device 10 according to an embodiment.

Per-pin training between the buffer chip 150 and the memory device 10 may be performed at various time points as described in FIG. 8, and FIG. 12 describes an embodiment in which per-pin training is performed between a time point at which DCC training is performed in the memory device 10 and a time point at which DCC training is performed in the buffer chip 150.

The controller 200 may perform power-on of the storage device and perform ZQ calibration S1200. For example, the controller 200 may detect power-on of the storage device and, in response to detecting power-on of the storage device, may perform ZA calibration.

After performing the ZQ calibration, the controller 200 may transmit a clock signal CLK to the buffer chip 150 in operation S1205. For example, the clock signal CLK may be nRE and may be for delay training of the buffer chip 150. The buffer chip 150 may transmit the clock signal CLK received from the controller 200 to the memory device 10 in operation S1210.

The memory device 10 may receive the clock signal CLK and select data in operation S1220. For example, the memory device 10 may select at least a portion of the second random data. The memory device 10 may transmit the data signal DQ and the data strobe signal DQS to the buffer chip 150 in operation S1225. For example, the memory device 10 may transmit the data signal DQ including the at least part of the second random data to the buffer chip 150.

The buffer chip 150 may receive the data signal DQ and the data strobe signal DQS and perform delay training, DCC training, and/or reference voltage training in operation S1230. For example, the buffer chip 150 may sample the data signal DQ and may compare the sampled data DATA with the second random data by sequentially adding a delay to the data signal strobe signal DQS. According to an embodiment, the buffer chip 150 may sequentially increase the reference voltage level of the data signal DQ and compare the sampled data DATA with the second random data. The buffer chip 150 may generate a pass/fail map of the data signal DQ based on a comparison result between the data DATA and the second random data. The buffer chip 150 may determine a target delay and/or a target reference voltage level based on the generated pass/fail map.

After completing delay training, DCC training, and/or reference voltage training for the memory device, the buffer chip 150 may select data in operation S1240. For example, the buffer chip 150 may select at least a portion of first random data.

The buffer chip 150 may transmit a data signal DQ′[n] and a data strobe signal DQS' to the controller 200 in operation S1245. For example, the buffer chip 150 may transmit the data signal SQ′[n] including the at least a portion of the first random data and the data strobe signal DQS' based on the clock signal to the controller 200. The controller 200 may perform delay training in operation S1250. For example, the controller 200 may perform delay training on the buffer chip 150 based on the received data signal DQ′[n] and the data strobe signal DQS' in operation S1250.

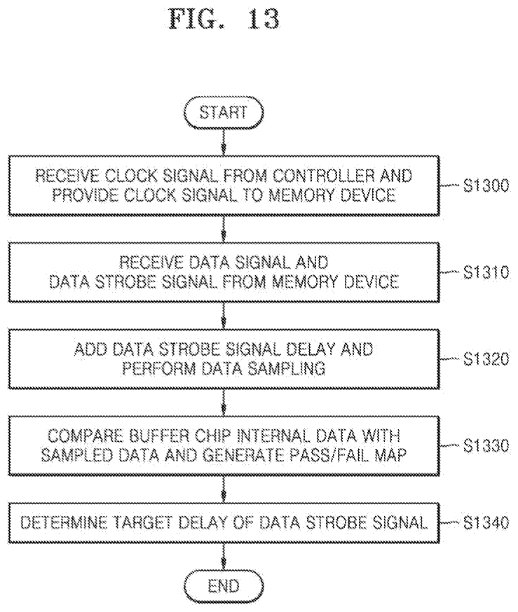

FIG. 13 is a flowchart of an operation of performing per-pin training by using a buffer chip in a storage device according to an embodiment. According to various embodiments, the operation of performing per-pin training may be implemented by the storage device 10 or the storage device 50 illustrated with respect to FIGS. 4-7D and described above.

In operation S1300, the buffer chip may receive a clock signal from the controller and provide the clock signal to the memory device.

For example, the buffer chip may receive the read enable signal nRE acquired from the controller and provide the read enable signal nRE to the memory device.

In operation S1310, the buffer chip may receive a data signal and a data strobe signal from the memory device. For example, the memory device may transmit a data signal including at least a portion of the second random data to the buffer chip. The buffer chip may receive a data signal and a data strobe signal through an input buffer.

In operation S1320, the buffer chip may add a delay strobe signal delay and perform data sampling. For example, the buffer chip may add a delay to the data strobe signal in the delay circuit and sample the data signal based on the delayed data strobe signal. The sampled data may be synchronized to the rising or falling edge of the delayed data strobe signal.

In operation S1330, the buffer chip may compare internal data with sampled data and generate a pass/fail map. For example, the buffer chip may compare internal data that is internal to the buffer chip with sampled data and generate the pass/fail map. The buffer chip may determine a pass when the sampled data and internal data are the same, and a fail when the sampled data and internal data are different. The buffer chip may sequentially increase the delay time of the data strobe signal and generate a pass/fail map in which comparison results corresponding to each delay time are mapped.

In operation S1340, the storage device may determine a target delay of the data strobe signal. For example, the buffer chip may determine a first delay based on a time point at which the comparison result changes from fail to pass and a second delay based on a time point at which the comparison result changes from pass to fail. The buffer chip may determine an average value of the first delay and the second delay as the target delay. In the per-pin training method of a storage device including a buffer chip and a memory device according to various embodiments, the method may include transmitting, by the memory device, a random data signal and a data strobe signal to the buffer chip in response to receiving a clock signal, generating a delayed data strobe signal by delaying the data strobe signal by a delay time, generating sampled data by sampling the random data signal based on the delayed data strobe signal, generating a comparison result by comparing internal data with the sampled data, and determining a target delay based on the comparison result and delaying the data strobe signal by the target delay.

While various embodiments have been particularly shown and described with reference to the drawings, it will be understood that various changes in form and details may be made therein without departing from the spirit and scope of the following claims.

What is claimed is:

1. A storage device comprising:
a buffer chip; and
a memory device configured to transmit a random data signal and a data strobe signal to the buffer chip based on a clock signal received from the buffer chip,
wherein the buffer chip comprises:
a delay circuit configured to delay the data strobe signal by a delay time to generate a delayed data strobe signal;
a sampler configured to receive the delayed data strobe signal from the delay circuit and sample the random data signal based on the delayed data strobe signal to generate sampled data;
a comparator configured to compare internal data with the sampled data to generate a comparison result; and
a counter module configured to receive the comparison result from the comparator and determine a target delay based on the comparison result,
wherein the buffer chip delays the delayed data strobe signal based on the target delay.

2. The storage device of claim 1, wherein the comparison result is pass when the internal data and the sampled data are the same, and the comparison result is fail when the internal data and the sampled data are not the same, and
wherein the counter module comprises a counter that sequentially receives a plurality of comparison results from the comparator and accumulates and stores the plurality of comparison results that are sequentially received.

3. The storage device of claim 2, wherein the counter module comprises a first counter module that stores a first delay at a time point at which the plurality of comparison results that are sequentially received change from fail to pass, and that stores a second delay at a time point at which the plurality of comparison results that are sequentially received change from pass to fail, and
wherein the counter module averages the first delay and the second delay to generate the target delay.

4. The storage device of claim 3, wherein the counter module,
in response to confirming that the second delay is not stored in the first counter, provides a delay time increase signal to the delay circuit, and
in response to confirming that the second delay is stored in the first counter, does not provide the delay time increase signal to the delay circuit.

5. The storage device of claim 4, wherein the delay circuit increases the delay time by a preset time based on the delay time increase signal.

6. The storage device of claim 2, wherein the buffer chip further comprises:
a reference voltage generator configured to change a reference voltage for sampling the random data signal to generate a changed reference voltage; and
a duty cycle correction circuit configured to adjust a duty cycle of the random data signal based on a control signal,
wherein the sampler samples the random data signal based on the changed reference voltage or samples the random data signal having an adjusted duty cycle to generate the sampled data,
wherein the comparator compares the internal data and the sampled data to determine whether the internal data and the sampled data are identical and transmits a determination result to the counter module,
wherein the counter module comprises a second counter module that stores a first reference voltage level at a time point at which the comparison result changes from fail to pass and that stores a second reference voltage level at a time point at which the comparison result changes from pass to fail, and
wherein the second counter module determines an average value of the first reference voltage level and the second reference voltage level as a target reference voltage level.

7. The storage device of claim 6, wherein the counter module
provides a reference voltage increase signal to the reference voltage generator in response to confirming that the second reference voltage level is not stored in the second counter and
does not provide the reference voltage increase signal to the reference voltage generator in response to confirming that the second reference voltage level is stored in the second counter.

8. The storage device of claim 6, wherein the duty cycle correction circuit adjusts the duty cycle of the random data signal using a phase interpolation method.

9. The storage device of claim 7, wherein the reference voltage generator increases the reference voltage by a preset value based on the reference voltage increase signal.

10. The storage device of claim 1, wherein the internal data is the same as random data included in the random data signal and that is stored in the memory device, and the internal data is random data in which a logic high section and a logic low section are randomly switched.

11. The storage device of claim 1, further comprising a controller that provides the clock signal to the buffer chip,
wherein the buffer chip provides the clock signal that is obtained from the controller to the memory device.

12. The storage device of claim 1, wherein the buffer chip further comprises an input buffer that buffers the random data signal.

13. A buffer chip comprising:
a clock pin configured to receive a clock signal from outside the buffer chip;
a plurality of input/output pins including a first pin configured to provide the clock signal to a plurality of external memory chips and a second pin configured to receive a data signal and a data strobe signal from the plurality of external memory chips;
a delay circuit configured to delay the data strobe signal by a delay time to generate a delayed data strobe signal;
a sampler configured to sample a random data signal based on the delayed data strobe signal to generate sampled data;
a comparator configured to compare internal data with the sampled data to generate a comparison result; and
a counter module configured to determine a target delay based on the comparison result.

14. The buffer chip of claim 13, wherein the comparison result is pass when the internal data and the sampled data are the same and the comparison result is fail when the internal data and the sampled data are not the same, and
wherein the counter module sequentially receives a plurality of comparison results from the comparator and accumulates and stores the plurality of comparison results.

15. The buffer chip of claim 14, wherein the counter module comprises a first counter module that stores a first delay at a time point at which the plurality of comparison results that are sequentially received change from fail to pass, and that stores a second delay at a time point at which the plurality of comparison results that are sequentially received change from pass to fail, and
wherein the first counter module averages the first delay and the second delay to generate the target delay.

16. The buffer chip of claim 15, Wherein the counter module provides a delay time increase signal to the delay circuit in response to confirming that the second delay is not stored in the first counter and does not provide the delay time increase signal to the delay circuit in response to confirming that the second delay is stored in the first counter.

17. The buffer chip of claim 14, wherein the buffer chip further comprises a reference voltage generator configured to change a reference voltage for sampling the random data signal to generate a changed reference voltage, and
a duty cycle correction circuit configured to adjust a duty cycle of the random data signal based on a control signal,
wherein the sampler samples the random data signal based on the changed reference voltage or samples the random data signal having an adjusted duty cycle, to generate the sampled data,
wherein the comparator compares the internal data and the sampled data to determine whether the internal data and the sampled data are identical and transmits a determination result to the counter module,
wherein the counter module comprises a second counter module that stores a first reference voltage level at a time point at which the comparison result changes from fail to pass and that stores a second reference voltage level at a time point at which the comparison result changes from pass to fail, and
wherein the second counter module averages the first reference voltage level and the second reference voltage level to generate a target reference voltage level.

18. The buffer chip of claim 17, wherein the counter module
provides a reference voltage increase signal to the reference voltage generator in response to confirming that the second reference voltage level is not stored in the second counter and
does not provide the reference voltage increasing signal to the reference voltage generator in response to confirming that the second reference voltage level is stored in the second counter.

19. The buffer chip of claim 18, wherein the reference voltage generator increases the reference voltage by a preset value based on the reference voltage increase signal.

20. A per-pin training method of a storage device including a buffer chip and a memory device, the per-pin training method comprising:
transmitting, by the memory device, a random data signal and a data strobe signal to the buffer chip based on a clock signal received from the buffer chip;
delaying the data strobe signal by a delay time to generate a delayed data strobe signal;
sampling the random data signal based on the delayed data strobe signal to generate sampled data;
comparing internal data with the sampled data to generates a comparison result;
determining a target delay based on the comparison result; and
delaying the delayed data strobe signal based on the target delay.
